(19) United States
(12) Patent Application Publication
(10) Pub. No.: US 2002/0071501 A1
(43) Pub. Date: Jun. 13, 2002

(54) VSB receiver and method for processing receiving signal in the same

(76) Inventors: Young Mo Gu, Seoul (KR); Sung Ryong Hong, Kyonggi-do (KR)

Correspondence Address: BIRCH STEWART KOLASCH & BIRCH, PO BOX 747, FALLS CHURCH, VA, 22040-0747, US

(21) Appl. No.: 10/005,081

(22) Filed: Dec. 7, 2001

(30) Foreign Application Priority Data
Dec. 8, 2000 (KR) P2000-74726

(51) Int. Cl. H03D 1/24

(52) U.S. Cl. 375/321; 375/143

(57) ABSTRACT

A VSB receiver and a method for processing a receiving signal in the same are disclosed, which is not subject to frequency offset. The VSB receiver includes an intermediate frequency signal generator generating an intermediate frequency band signal from a received signal; a demodulator generating a complex base band signal consisting of an I channel signal and a Q channel signal using the intermediate frequency band signal and at least one local carrier wave signal; and a complex base band matched filter filtering at least one of the I channel signal and the Q channel signal. In the VSB receiver, since a complex signal responds to a required channel of the I channel and the Q channel, it is possible to prevent performance of the system from being deteriorated by frequency offset.

This application claims the benefit of the Korean Application No. P2000-74726 filed on Dec. 8, 2000, which is hereby incorporated by reference.

### BACKGROUND OF THE INVENTION

1. Field of the Invention

The present invention relates to a VSB receiver and a method for processing a receiving signal in the same.

2. Discussion of the Related Art

The United States of America has employed ATSC 8T-VSB (8 Trellis-Vestigial Sideband) as a standard since 1995, and has been broadcasting in the ATSC 8T-VSB since the later half of 1998. South Korea also has employed the ATSC 8T-VSB as a standard and started test broadcasting.

If amplitude modulation of a single carrier wave is implemented using a base band signal, the same output signal is received in an upper side band wave and a lower side band wave based on the single carrier wave on a frequency spectrum.

In view of efficiency of a frequency band, it is not desirable that the output signal is transmitted through a transmission channel. Therefore, a modulation system that can transmit either an upper side band wave or a lower side band wave is required. Examples of the modulation system include a single side band (SSB) modulation system and a VSB modulation system. These modulation systems are almost similar to each other. However, the VSB modulation system is different from the SSB modulation system in that a transmitting side additionally transmits a portion of other side band waves to allow a receiving side to easily implement demodulation.

FIG. 1 illustrates a related art VSB communication system for a terrestrial digital television.

Referring to FIG. 1, a transmitter includes a first multiplier 11 and a first pass band matched filter 12. The first multiplier 11 modulates an input signal x(t) of a VSB base band to a carrier signal 2 coswct. The first pass band matched filter 12 modulates an output signal of the first multiplier 11 to a VSB signal. In FIG. 1, a receiver includes a second multiplier 13, a second pass band matched filter 14, and a third multiplier 15.

The second multiplier 13 multiplies a signal transmitted from the transmitter by an intermediate frequency signal 2cos(wc−wi)t to modulate the resultant signal to an intermediate frequency band signal.

The second pass band matched filter 14 filters the intermediate frequency band signal output from the second multiplier 13 to generate a given pass band signal.

The third multiplier 15 demodulates the signal filtered by the second pass band matched filter 14 to a local carrier signal 2coswit.

The operation of the aforementioned related art VSB communication system will be described with reference to the accompanying drawings.

The first multiplier 11 modulates the input signal x(t) as shown in FIG. 2A to the carrier signal 2coswct and outputs a signal as shown in FIG. 2B. The first pass band matched filter 12 filters the output signal of the first multiplier 11 and outputs a specific pass band signal which is a VSB modulated signal as shown in FIG. 2C.

The VSB modulated signal is transmitted from the transmitter to the receiver and can be expressed as follows.

v′c(t)=x′(t) coswct+x′hsinwct (1)

The VSB modulated signal, as shown in the above equation (1), is obtained by adding a signal xˆ ′h(t) modulated by the carrier wave coswct to a signal xˆ ′h(t) modulated by a carrier wave signal sinwct. The signal xˆ ′h(t) is a Q channel signal and is a hilbert-converted type of an I channel signal xˆ ′(t).

FIG. 2D illustrates a spectrum of the signal xˆ ′h(t), and FIG. 2E illustrates a spectrum of the signal xˆ ′(t).

The signal xˆ ′(t) and the signal xˆ ′h(t) have a mutual relation on the spectrum. That is, lower side band waves of these signals have the same values as each other while their upper side band waves have the same size as each other but have opposite signs to each other. Therefore, if these signals are added to each other, the lower side wave remains only. In other words, the band width of the signals is reduced to half.

The second multiplier 13 serves as a tuner and multiplies a receiving signal by the intermediate frequency signal 2cos(wc−wi)t to tune the VSB modulated signal in a desired band, thereby generating an intermediate frequency band signal as shown in FIG. 2F.

Subsequently, the second band pass matched filter 14 filters the intermediate frequency band signal and outputs the specific band signal as shown in FIG. 2G.

The signal output from the second multiplier 13 can be expressed as follows.

v′i(t)=x′(t) cos wi(t)+x′h sin wit (2)

Also, the signal passed through the second band pass matched filter 14 can be expressed as follows.

vi(t)=x(t)+cos wct+xh sin wit (3)

The signal output through the second band pass matched filter 14 is demodulated by the third multiplier 15 using the local carrier wave signal 2coswit. The demodulated signal r(t) can be expressed as follows.

r(t)=x(t)+hfc (4)

In the equation (4), hfc represents a high frequency component and is removed when the receiving signal passes through the second band pass matched filter 14. Accordingly, once the high frequency component hfc is removed, a base band signal x(t) as shown in FIG. 2H is only detected.

However, when the received signal is converted to the intermediate band signal by the tuner, as shown in FIGS. 3A and 3B, frequency offset may be generated (w′i>wi, w′i<wi).

In this case, the received signal is converted to the intermediate frequency signal w′i. When the intermediate frequency signal passes through the second pass band matched filter 14, an edge of the frequency spectrum may be cut.

The signal in which the edge of the frequency spectrum is cut is multiplied by the local carrier wave signal 2cosw′it so that a demodulated signal r′(t) is obtained as follows.

rˆ ′(t)=x(t)+isi+hfc (5)

In the equation (5), isi means inter-symbol interference and is generated when the signal passes through the second band pass matched filter 14.

To remove loss of the matched filter due to the frequency offset generated in the tuner, a base band matched filter 25 may be used as shown in FIG. 4.

Referring to FIG. 4, the received signal transmitted from the transmitter is converted to the intermediate frequency band signal by the second multiplier 23 in the tuner. The converted signal is multiplied by the local carrier wave signal in the third multiplier 24. Then, the output signal of the third multiplier 24 is filtered by the base band matched filter 25.

The base band matched filter 25 is generally used in a qudrature amplitude modulation (QAM) receiver. The base band matched filter 25 cannot be used in the VSB receiver. If the received signal is demodulated in the base band without passing through the band pass matched filter, the demodulated signal can be expressed as follows.

rˆ ′(t)=xˆ ′(t)+hfc (6)

In the equation (6), since the transmitter and the receiver respectively use a square root matched filter as the VSB matched filter, as shown in FIGS. 5A and 5B, the frequency spectrum of the base band signal xˆ ′(t) peaks out near DC components. To flatten the DC components on the frequency spectrum, two band pass matched filters are required. However, if the two band pass matched filters are used, a problem arises in that the VSB receiver is subject to the frequency offset generated in the tuner.

### SUMMARY OF THE INVENTION

Accordingly, the present invention is directed to a VSB receiver and a method for processing a receiving signal in the same that substantially obviates one or more problems due to limitations and disadvantages of the related art.

An object of the present invention is to provide a VSB receiver and a method for processing a receiving signal in the same that is not subject to frequency offset.

Another object of the present invention is to provide a VSB receiver and a method for processing a receiving signal in the same that is based on a complex base band.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a VSB receiver according to the present invention includes a complex base band matched filter that uses an I channel signal and a Q channel signal.

In another aspect of the present invention, a VSB receiver includes an intermediate frequency signal generator generating an intermediate frequency band signal from a received signal; a demodulator generating a complex base band signal consisting of an I channel signal and a Q channel signal using the intermediate frequency band signal and at least one local carrier wave signal; and a complex base band matched filter filtering at least one of the I channel signal and the Q channel signal.

In another aspect of the present invention, a VSB receiver includes: a first multiplier multiplying a receiving signal by an intermediate frequency signal to generate an intermediate frequency band signal; a second multiplier multiplying the intermediate frequency band signal by a first local carrier wave signal to demodulate the resultant value to an I channel signal; a third multiplier multiplying the intermediate frequency band signal by a second local carrier wave signal to demodulate the resultant value to a Q channel signal; and a complex base band matched filter filtering at least one of the demodulated I channel signal and the demodulated Q channel to output a complex signal.

In another aspect of the present invention, a method for processing a signal in a VSB receiver having a tuner, includes the steps of: generating an intermediate frequency band signal by multiplying a received signal through the tuner by an intermediate frequency signal; generating a complex base band signal consisting of an I channel signal and a Q channel signal by multiplying the intermediate frequency band signal by an I channel local carrier wave signal and a Q channel local carrier wave signal; and complex matched filtering at least one of the I channel signal and the Q channel signal.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a diagram illustrating a related art VSB communication system for a terrestrial digital broadcasting;

FIGS. 2A to 2H are diagrams illustrating frequency spectrums of VSB signals on the VSB communication system of FIG. 1;

FIGS. 3A and 3B are diagrams illustrating loss due to frequency offset in the VSB communication system of FIG. 1;

FIG. 4 is a block diagram illustrating a related art VSB communication system that employs a base band matched filter;

FIG. 5A is a block diagram illustrating a frequency spectrum of a signal before passing through a base band matched filter in the system of FIG. 4;

FIG. 5B is a diagram illustrating a frequency spectrum of a signal after passing through a base band matched filter in the system of FIG. 4;

FIG. 6 is a block diagram illustrating a VSB receiver according to the present invention;

FIGS. 7A and 7B are block diagrams illustrating a complex base band matched filter according to one embodiment of the present invention;

FIGS. 8A to 8C are diagrams illustrating frequency characteristics of the complex base band signal;

FIGS. 9A to 9C are diagrams illustrating frequency characteristics of the complex base band matched filter; and

FIGS. 10A and 10B are diagrams illustrating frequency spectrums of signals output from the complex base band matched filter.

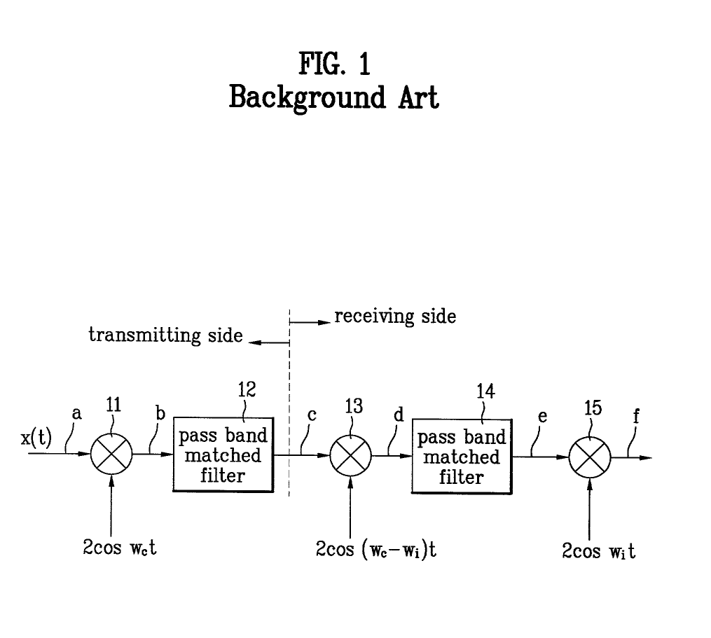

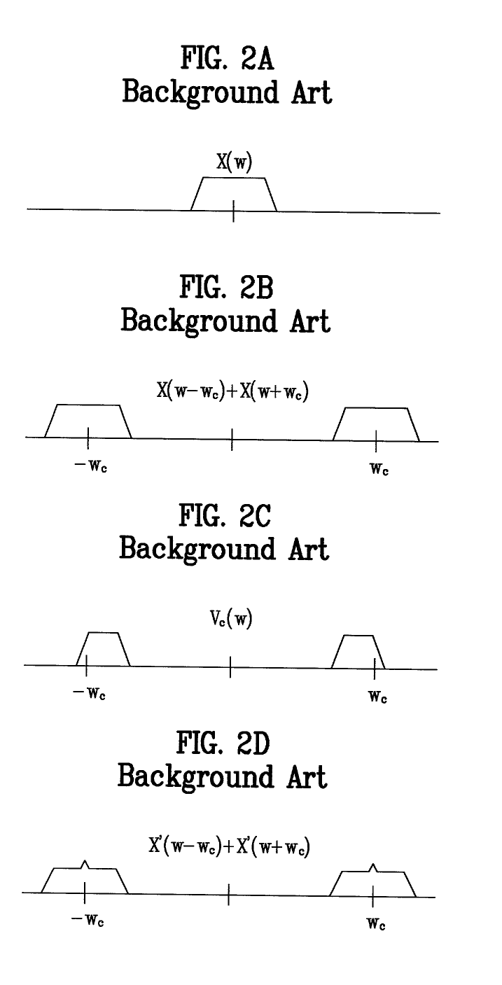

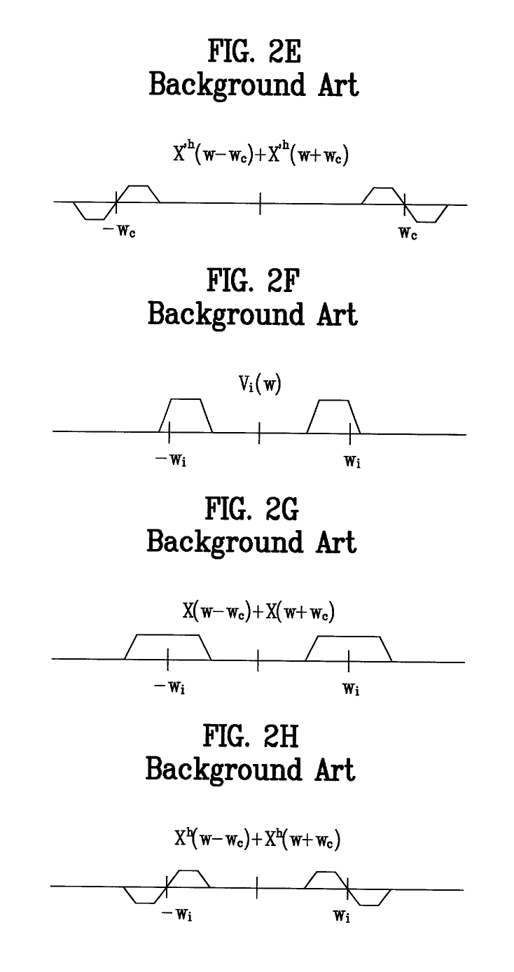

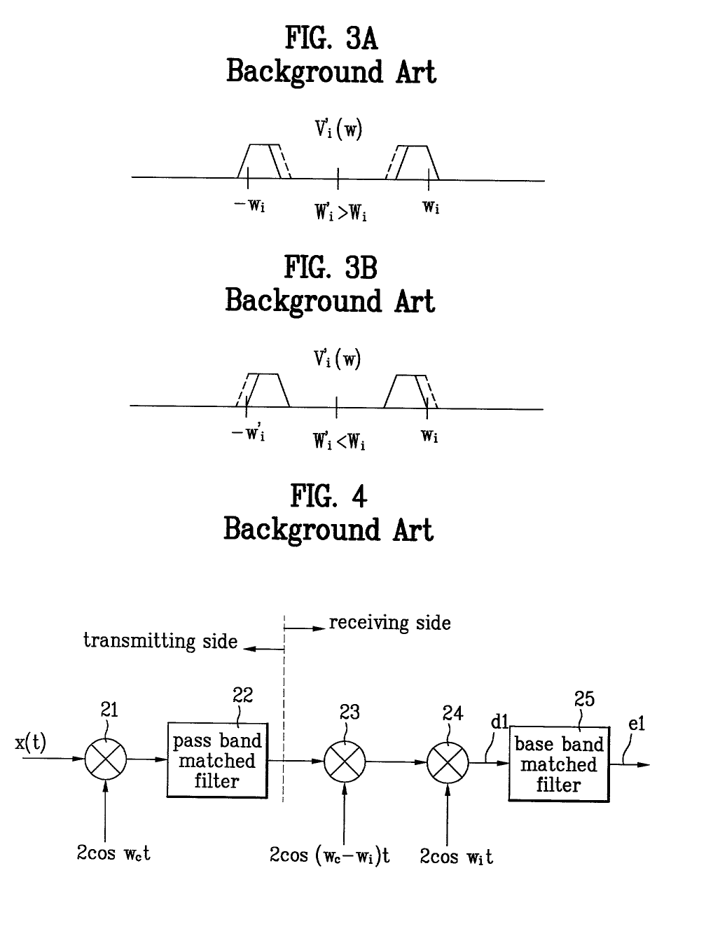

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

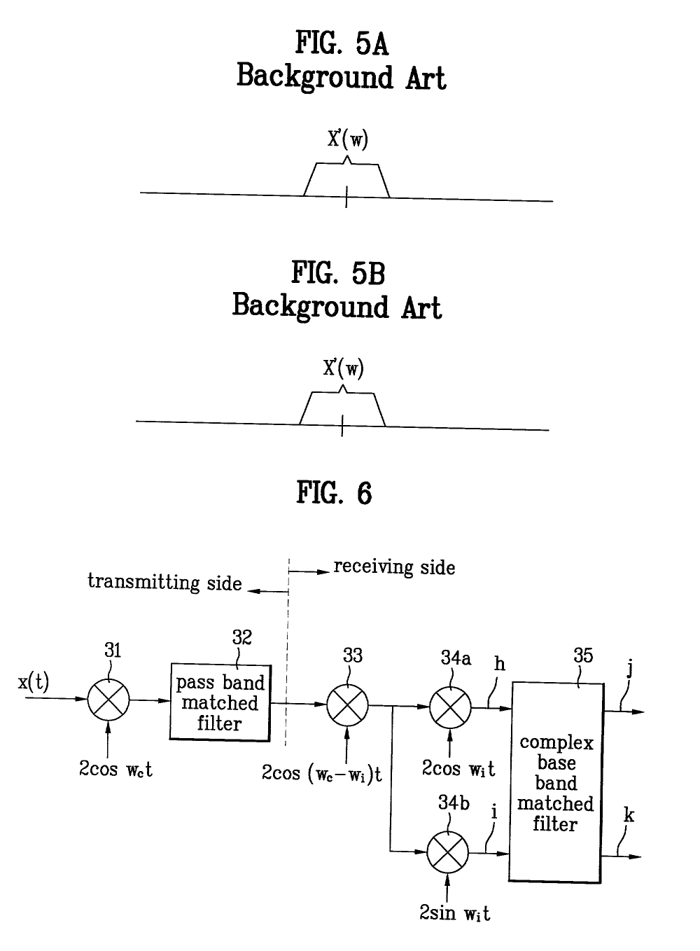

A VSB communication system according to the present invention will be described with reference to FIG. 6.

Referring to FIG. 6, a transmitter of the VSB communication system includes a fourth multiplier 31 multiplying an input signal x(t) by a carrier wave signal 2coswct to modulate the input signal x(t), and a third pass band matched filter 32 filtering an output signal of the fourth multiplier 31 in a desired pass band.

A receiver of the VSB communication system includes a fifth multiplier 33 multiplying a signal received from the transmitter by an intermediate frequency signal 2cos(wc−wi)t to generate an intermediate frequency band signal, a sixth multiplier 34a multiplying the output signal of the fifth multiplier 33 by a local carrier wave signal 2coswit to demodulate the output signal to an I channel signal, a seventh multiplier 34b multiplying the output signal of the fifth multiplier 33 by a local carrier wave signal 2sinwit to demodulate the output signal to a Q channel signal, and a complex base band matched filter 35 implementing matched filtering using the I channel signal from the sixth multiplier 34a as a real domain input signal and the Q channel signal from the seventh multiplier 34b as an imaginary domain input signal and outputting a complex signal.

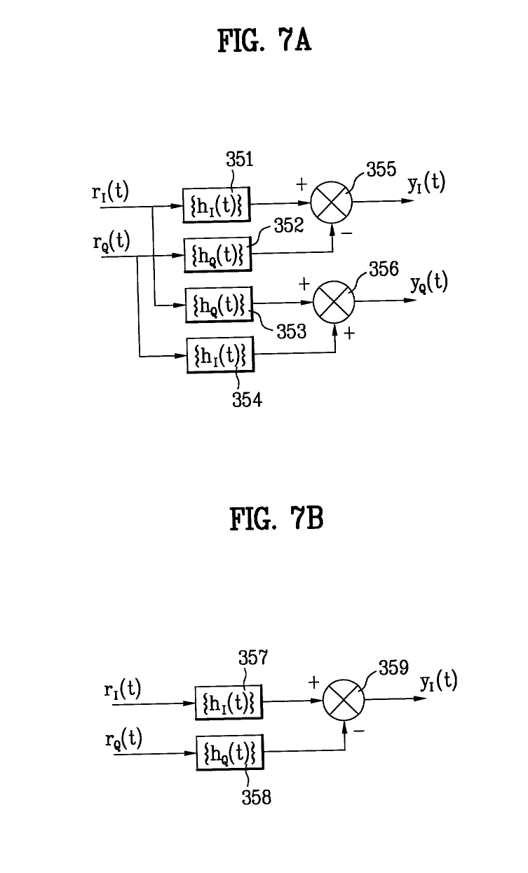

FIG. 7A is a diagram illustrating the complex base band matched filter 35 when the I channel and the Q channel are required. Referring to FIG. 7A, the complex base band matched filter 35 includes a first base band matched filter 351 filtering a real domain of the I channel signal, a second base band matched filter 353 filtering an imaginary domain of the I channel signal, a third base band matched filter 352 filtering a real domain of the Q channel signal, a fourth base band matched filter 354 filtering an imaginary domain of the Q channel signal, a first adder 355 adding the filtered real domain signals output from the first base band matched filter 351 and the second base band matched filter 352 to output the resultant value as a new I channel signal, and a second adder 356 adding the filtered imaginary domain signals output from the third base band matched filter 353 and the fourth base band matched filter 354 to output the resultant value as a new Q channel signal.

FIG. 7B is a block diagram illustrating the complex base band matched filter 35 when the I channel signal is only required.

As shown in FIG. 7B, the complex base band matched filter 35 includes a fifth base band matched filter 357 filtering the I channel signal, a sixth base band matched filter 358 filtering the Q channel signal, and a third adder adding the filtered I channel signal used as the real domain value to the filtered Q channel signal used as the imaginary domain value and outputting the added complex signal as a new I channel signal.

The complex base band matched filter 35 for the VSB receiver will be described with reference to the accompanying drawings.

Referring to FIG. 6, the transmitter includes a fourth multiplier 31 and a third pass band matched filter 32.

The fourth multiplier 31 multiplies the input signal x(t) by the carrier wave signal 2coswct to modulate the input signal. The modulated signal is transmitted to the receiver through the third pass band matched filter 32.

Meanwhile, the fifth multiplier 33 corresponding to the tuner of the receiver multiplies the received signal by the intermediate frequency signal 2cos(wc−wi)t to output the intermediate frequency band signal.

The intermediate frequency band signal is respectively input to the sixth multiplier 34a and the seventh multiplier 34b.

The sixth multiplier 34a, as shown in FIG. 5A, multiplies the intermediate frequency band signal by the first local carrier wave signal 2coswit to demodulate the intermediate frequency band signal to the I channel signal h. The seventh multiplier 34b, as shown in FIG. 5B, the intermediate frequency band signal by the second local carrier wave signal 2sinwit to demodulate the intermediate frequency band signal to the Q channel signal i.

Supposing that the base band signal demodulated by multiplying the first local carrier wave signal 2coswit generated by the VSB receiver by the intermediate frequency band signal is r_I(t), the signal r_I(t) can be expressed as follows.

r_{—}I(t)=xˆ ′(t) (7)

In the equation (7), for the convenience, the high frequency component hfc has been omitted.

Meanwhile, supposing that the base band signal demodulated by multiplying the second local carrier wave signal 2sinwit by the intermediate frequency band signal is r_Q(t), the signal r_Q(t) can be expressed as follows.

r_{—}Q(t)=xˆ ′h(t) (8)

Supposing that the base band signal r_I(t) is the I channel signal, the base band signal r_Q(t) is the Q channel signal, the I channel signal is the real domain signal, and the Q channel signal is the imaginary domain signal, the base band signal r(t) becomes the complex signal as follows.

r(t)=r_{—}I(t)+jr_{—}Q(t) (9)

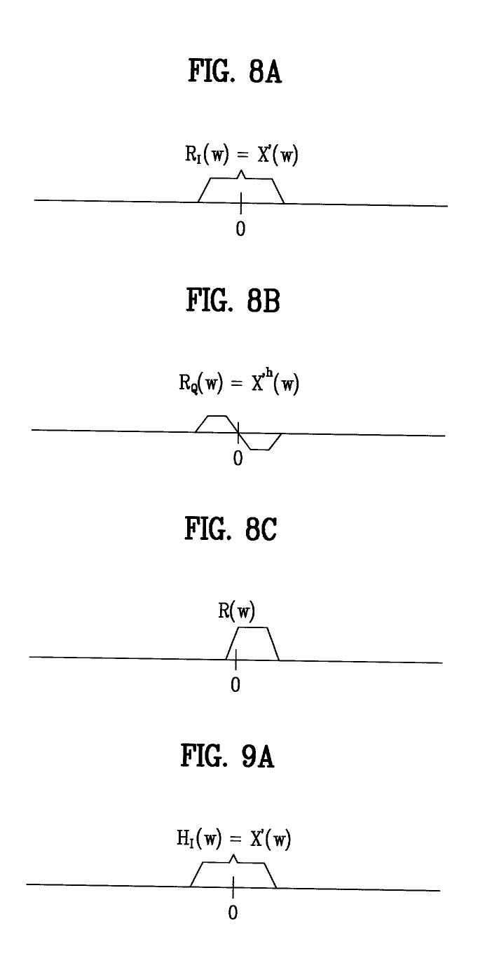

The complex signal has a frequency spectrum that is asymmetrical around 0, as shown in FIGS. 8A and 8B. FIG. 8A illustrates a frequency spectrum of the I channel signal, FIG. 8B illustrates a frequency spectrum of the Q channel signal, and FIG. 8C illustrates a frequency spectrum of the base band signal r(t). The complex base band matched filter 35 has the same frequency characteristic as that of the transmitting signal.

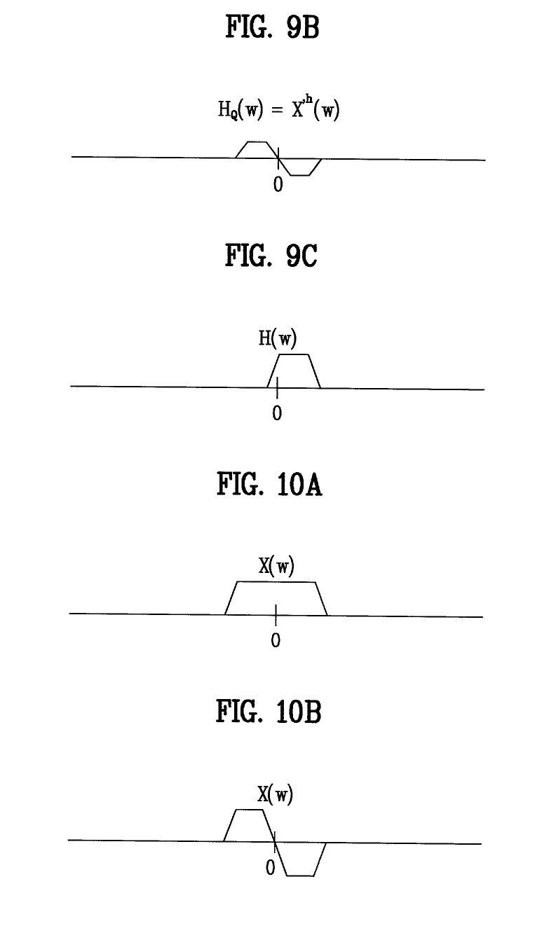

Meanwhile, FIGS. 9A to 9C are diagrams illustrating frequency characteristics of the complex base band matched filter. FIG. 9A illustrates the frequency characteristic of the I channel signal, FIG. 9B illustrates the frequency characteristic of the Q channel signal, and FIG. 9C illustrates the whole frequency characteristic of the matched filter 35.

The complex base band matched filter 35 of the receiver should be designed in such a manner that the frequency spectrum R(w) of the base band signal r(t) shown in FIG. 8C is equal to the frequency characteristic H(w) of the complex base band matched filter 35 shown in FIG. 9C.

In other words, the characteristic h(t) of the complex base band matched filter 35 should adapt to the conditions that the frequency characteristic H(w) is equal to the frequency spectrum R(w).

Since the base band signal r(t) is a complex signal type, the characteristic h(t) of the base band matched filter includes a characteristic of the complex filter as follows.

h(t)=h_{—}I(t)+jh_{—}Q(t) (10)

The I channel filter and the Q channel filter respectively have the following frequency characteristic.

H_{—}I(t)={Xˆ ′}_{—}I(w) (11)

H_{—}Q(t)={Xˆ ′h}_{—}I(w) (12)

Once the complex base band signal r(t) passes through the complex base band matched filter 35, output signals yI(t) and yQ(t) of the filter 35 can respectively be expressed as follows.

yI(t)=hI(t)×rI(t)−Q(t)×rQ(t)=x(t) (13)

yQ(t)=hI(t)×rQ(t)+hQ(t)×rI(t)=Xh(t) (14)

In the equation (13), yI(t) is the I channel output signal. In the equation (14), yQ(t) is the Q channel output signal. The I channel output signal yI(t) is the signal x(t) transmitted from the transmitter.

As described above, the I channel signal r_I(t) and the Q channel signal r_Q(t) are input to the complex base band matched filter 35, as shown in FIG. 7. Then, when the I channel and the Q channel are required, the filter 35, as shown in FIG. 7A, filters the I channel signal r_I(t) and the Q channel signal r_Q(t), respectively.

Meanwhile, when the I channel is only required, the filter 35 filters the I channel signal r_I(t) only as shown in FIG. 7B.

When the I channel and the Q channel are required, as shown in FIG. 7A, the filter 35 filters the I channel signal r_I(t) through the first base band matched filter 351 and the third base band matched filter 353. At this time, the filtered I channel signal r_I(t) becomes real domain signals of the I channel and the Q channel.

The Q channel signal is input to the second base band matched filter 352 and the fourth base band matched filter 354 and then filtered. At this time, the Q channel signal becomes imaginary domain signals of the I channel and the Q channel.

The first adder 355 adds the output signal of the first base band matched filter 351 received as a positive real domain signal to the output signal of the second base band matched filter 352 received as a negative imaginary domain signal, thereby obtaining a resultant signal yI(t). The added resultant signal yI(t) can be expressed as yI(t)=hI(t)×rI(t)−hQ(t)×rQ(t) as shown in the equation (13).

The second adder 356 adds the output signal of the second base band matched filter 352 received as a positive real domain signal to the output signal of the fourth base band matched filter 354 received as a negative imaginary domain signal, thereby obtaining a resultant signal yQ(t). The added resultant signal yQ(t) can be expressed as yQ(t)=hI(t)×rQ(t)+hQ(t)×rI(t) as shown in the equation (14).

Meanwhile, when the I channel is only required, the filter 35 filters the I channel signal r_I(t) through the fifth base band matched filter 357 and the Q channel signal r_Q(t) through the sixth base band matched filter 358.

The third adder 359 adds the output signal of the fifth base band matched filter 357 received as a positive real domain signal to the output signal of the sixth base band matched filter 358 received as a negative imaginary domain signal, thereby obtaining a resultant signal yI(t). The added resultant signal yI(t) is output as the I channel signal and can be expressed as yI(t)=hI(t)×rI(t)−hQ(t)×rQ(t) as shown in the equation (13).

As described above, the filter 35 implements complex matched filtering for at least one of the I channel signal and the Q channel signal or both of them.

FIGS. 10A and 10B illustrate frequency spectrums of signals output from the complex base band matched filter 35. As shown in FIGS. 10A and 10B, the VSB receiver of the present invention is not subject to the frequency offset.

The aforementioned embodiment of the present invention has been described provided that the VSB system is in a successive signal processing region. However, the same advantage can be obtained even in case where the VSB system is in a discrete signal processing region.

As described above, the VSB receiver of the present invention has the following advantages.

The VSB receiver having the complex base band matched filter generates the complex signal using the I channel signal and the Q channel signal of the received signals and implements complex matched filtering for the required channel(s) only. Therefore, the frequency offset that may be generated in the tuner can be prevented from occurring, thereby deteriorating performance of the VSB receiver.

It will be apparent to those skilled in the art than various modifications and variations can be made in the present invention. Thus, it is intended that the present invention covers the modifications and variations of this invention provided they come within the scope of the appended claims and their equivalents.

What is claimed is:

1. A VSB receiver comprising:
an intermediate frequency signal generator generating an intermediate frequency band signal from a received signal;
a demodulator generating a complex base band signal consisting of an I channel signal and a Q channel signal using the intermediate frequency band signal and at least one local carrier wave signal; and
a complex base band matched filter filtering at least one of the I channel signal and the Q channel signal.

2. The VSB receiver of claim 1, wherein the complex base band matched filter includes a first base band matched filter filtering a real domain of the I channel signal, a second base band matched filter filtering an imaginary domain of the I channel signal, a third base band matched filter filtering a real domain of the Q channel signal, a fourth base band matched filter filtering an imaginary domain of the Q channel signal, a first adder adding the filtered real domain signals of the I channel and the Q channel output from the first base band matched filter and the second base band matched filter to output the resultant value as a new I channel signal, and a second adder adding the filtered imaginary domain signals of the I channel and the Q channel output from the second base band matched filter and the fourth base band matched filter to output the resultant value as a new Q channel signal.

3. The VSB receiver of claim 1, wherein the complex base band matched filter is designed so that a frequency characteristic H(w) is identical to a frequency spectrum R(w) of the base band signal.

4. The VSB receiver of claim 1, wherein the complex base band matched filter includes a fifth base band matched filter filtering the I channel signal, a sixth base band matched filter filtering the Q channel signal, and a third adder adding the filtered I channel signal to the real domain and the filtered Q channel signal to the imaginary domain to output the added complex signal as a new I channel signal.

5. A VSB receiver comprising:
a first multiplier multiplying a receiving signal by an intermediate frequency signal to generate an intermediate frequency band signal;
a second multiplier multiplying the intermediate frequency band signal by a first local carrier wave signal to demodulate the intermediate frequency band signal to an I channel signal;
a third multiplier multiplying the intermediate frequency band signal by a second local carrier wave signal to demodulate the intermediate frequency band signal to a Q channel signal; and
a complex base band matched filter filtering at least one of the demodulated I channel signal and the demodulated Q channel to output a complex signal.

6. The VSB receiver of claim 5, wherein the complex base band matched filter is designed so that a frequency characteristic H(w) is identical to a frequency spectrum R(w) of the base band signal.

7. The VSB receiver of claim 5, wherein the complex base matched filter includes a first base band matched filter filtering a real domain of the I channel signal, a second base band matched filter filtering an imaginary domain of the I channel signal, a third base band matched filter filtering a real domain of the Q channel signal, a fourth base band matched filter filtering an imaginary domain of the Q channel signal, a first adder adding the filtered real domain signals of the I channel and the Q channel output from the first base band matched filter and the second base band matched filter to output the resultant value as a new I channel signal, and a second adder adding the filtered imaginary domain signals of the I channel and the Q channel output from the second base band matched filter and the fourth base band matched filter to output the resultant value as a new Q channel signal.

8. The VSB receiver of claim 5, wherein the complex base band matched filter includes a fifth base band matched filter filtering the I channel signal, a sixth base band matched filter filtering the Q channel signal, and a third adder adding the filtered I channel signal to the real domain and the filtered Q channel signal to the imaginary domain to output the added complex signal as a new I channel signal.

9. The VSB receiver of claim 5, wherein the intermediate frequency signal is 2cos(wc−wi)t.

10. The VSB receiver of claim 5, wherein the first local carrier wave is 2coswit, and the second local carrier wave is 2sinwit.

11. A method for processing a signal in a VSB receiver having a tuner, the method comprising the steps of:
generating an intermediate frequency band signal by multiplying a received signal through the tuner by an intermediate frequency signal;
generating a complex base band signal consisting of an I channel signal and a Q channel signal by multiplying the intermediate frequency band signal by an I channel local carrier wave signal and a Q channel local carrier wave signal; and
complex matched filtering at least one of the I channel signal and the Q channel signal.

12. The method of claim 11, wherein the intermediate frequency signal is 2cos(wc−wi)t.

13. The method of claim 11, wherein the first local carrier wave is 2coswit, and the second local carrier wave is 2sinwit.
